(19) United States
(12) Patent Application Publication
(10) Pub. No.: US 2010/0147575 A1
(43) Pub. Date: Jun. 17, 2010

(54) PRINTED CIRCUIT BOARD AND MANUFACTURING METHOD THEREOF

(75) Inventors: Han-Ul Lee, Seoul (KR); Young-Hwan Shin, Yuseong-gu (KR); Jong-Jin Lee, Yuseong-gu (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/614,057

(22) Filed: Nov. 6, 2009

(30) Foreign Application Priority Data
Dec. 17, 2008 (KR) 10-2008-0128775

(51) Int. Cl. H05K 1/11; C25D 5/02

(52) U.S. Cl. 174/262; 174/264; 205/114

(57) ABSTRACT

A printed circuit board and a method of manufacturing the printed circuit board are disclosed. The method of manufacturing a printed circuit board can include: processing a first hole, which has a tapered shape, in one side of a substrate by using a laser drill; processing a second hole, which has a tapered shape and which connects with the first hole, in the other side of the substrate by using a laser drill in a position corresponding to that of the first hole; and forming a conductive portion, which electrically connects both sides of the substrate through the first hole and the second hole, by performing plating. This method may be used for providing reliable interlayer connections.

### CROSS-REFERENCE TO RELATED APPLICATIONS

This application claims the benefit of Korean Patent Application No. 10-2008-0128775, filed with the Korean Intellectual Property Office on Dec. 17, 2008, the disclosure of which is incorporated herein by reference in its entirety.

### BACKGROUND

1. Technical Field

The present invention relates to a printed circuit board and to a method of manufacturing the printed circuit board.

2. Description of the Related Art

In a printed circuit board, electrical connections can be implemented between different layers by processing vias in the substrates and chemically or electrically plating the insides of the vias. Two typical types of vias used in a printed circuit board, namely, the plated through-hole (PTH) and the blind via hole (BVH), are shown in FIGS. 1A and 1B.

The plated through-hole, which may completely penetrate through a printed circuit board, can be processed using a drill bit. The plated through-hole may be used, for example, to interconnect either side of a double-sided printed circuit board or to provide interlayer connection to the core layer in a multilayered printed circuit board. A plated through-hole processed using a drill bit can be shaped as a cylinder, having a substantially constant cross-section.

The blind via hole, on the other hand, may be structured to have one side blocked, and can be processed using laser processing. The cross-section of a blind via hole can be shaped as an inverted trapezoid, where the size of the via is bigger at the side from which the laser is irradiated compared to the size of the via at the bottom.

With the printed circuit board trending towards higher densities, there are continued demands not only for reduced line widths in the circuits, but also for reduced via sizes and land sizes. However, in processing plated through-holes having ultra-small diameters (of less than 100 μm), it may not be suitable to employ the conventional method of using a drill bit. This is because the hardness of a drill bit is proportional to the square of the drill diameter, and reducing the size of the drill bit will greatly reduce the hardness. While it is possible to overcome the problem of reduced hardness by increasing the rotation speed of the drill, there is a limit to how fast a CNC drill can be made to rotate. As such, processing ultra small plated through-holes using a conventional drill bit can entail many difficulties and incur high costs.

In order to process ultra small plated through-holes required for high density printed circuit boards in an effective and economical manner, there is a need for a plated through-hole processing technology that uses laser processing instead of drill processing.

Processing holes using laser can result in holes having a tapered shape, since the energy of the laser is greatest at the center. A method of processing a plated through-hole using laser may involve irradiating the laser several times from one side to form a tapered hole, much like the method used for processing a blind via hole, and then plating the inside of the hole to produce the plated through-hole.

With plated through-holes, it is advantageous to have a constant size and shape for the holes at the perforated bottom, as these relate to the quality of the plating and the filling of the holes. However, conventional methods of laser drill processing may result in smaller sizes and greater irregularity in size and shape in the holes at the perforated bottom.

When the bottom holes are smaller, there is a greater risk of blockage occurring near the bottom portion of the hole during the plating. If blockage occurs at one side during the processing of an ultra small plated through-hole, the flow of the plating liquid may be impeded. This may result in defects where portions are unplated or plated with irregular thickness, or may prevent the adequate filling of solder resist or resin after the plating procedure, increasing the likelihood of voids forming within the vias.

While it is possible to control the size and shape of the bottom holes by increasing the energy of the laser and/or the number of laser shots, this can lower the productivity of the laser drilling process and can lead to excessive processing of the insulating layer, causing the same problems of defective plating and voids in the vias as in the case of small hole sizes.

### SUMMARY

An aspect of the invention is to provide a printed circuit board and a method of manufacturing the printed circuit board that provide reliable interlayer connections.

Another aspect of the invention provides a method of manufacturing a printed circuit board, where the method includes: processing a first hole, which has a tapered shape, in one side of a substrate using a laser drill; processing a second hole, which has a tapered shape and which connects with the first hole, in the other side of the substrate using a laser drill in a position corresponding to that of the first hole; and forming a conductive portion, which electrically connects both sides of the substrate through the first hole and the second hole, by performing plating.

The conductive portion can be formed to completely fill the first hole and the second hole. Here, the inclination of an inner wall of the first hole may be an angle larger than or equal to 15 and smaller than or equal to 45 degrees. Also, a bottom portion of the first hole located in the middle of the substrate can have a size that is larger than or equal to 50% and smaller than or equal to 70% of the size of a surface portion of the first hole.

In certain embodiments, the first hole and the second hole can be substantially symmetrical.

Still another aspect of the invention provides a printed circuit board that includes: a substrate; a first hole having a tapered shape that is formed in one side of the substrate; a second hole having a tapered shape that is formed in the other side of the substrate and is connected with the first hole; and a conductive portion that electrically connects both sides of the substrate by way of the first hole and the second hole.

The first hole and the second hole can be formed substantially symmetrically, and the conductive portion can be formed to completely fill the first hole and the second hole. Here, the inner wall of the first hole can be inclined by an angle of 15 to 45 degrees, and a bottom portion of the first hole located in a middle of the substrate can be 50% to 70% of the size of a surface portion of the first hole.

Additional aspects and advantages of the present invention will be set forth in part in the description which follows, and in part will be obvious from the description, or may be learned by practice of the invention.

### BRIEF DESCRIPTION OF THE DRAWINGS

FIG. 1A and FIG. 1B are cross-sectional views of vias for a printed circuit board according to the related art.

FIG. 2 is a flowchart illustrating a method of manufacturing a printed circuit board according to an embodiment of the invention.

FIG. 3, FIG. 4, FIG. 5, FIG. 6, FIG. 7, FIG. 8, FIG. 9, FIG. 10, and FIG. 11 each represent a process in a method of manufacturing a printed circuit board according to an embodiment of the invention.

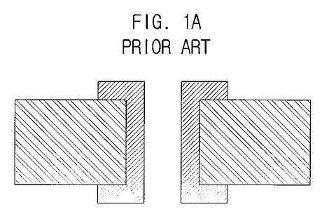

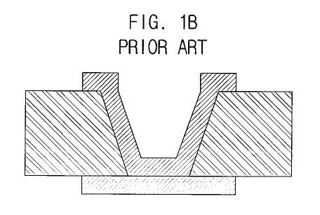

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention.

The printed circuit board, and the method of manufacturing the printed circuit board, according to certain embodiments of the invention will be described below in more detail with reference to the accompanying drawings. Those components that are the same or are in correspondence are rendered the same reference numeral regardless of the figure number, and redundant explanations are omitted.

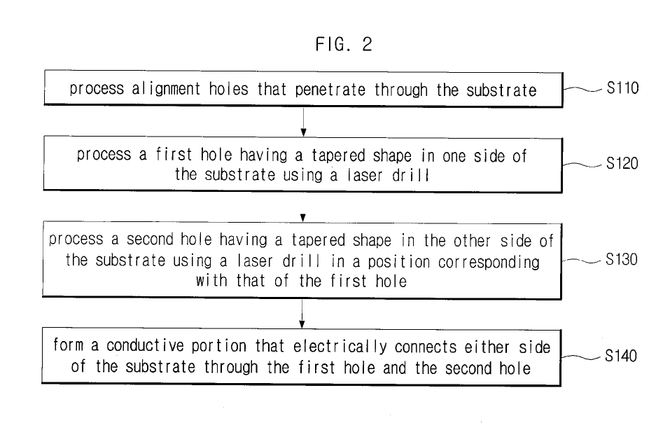

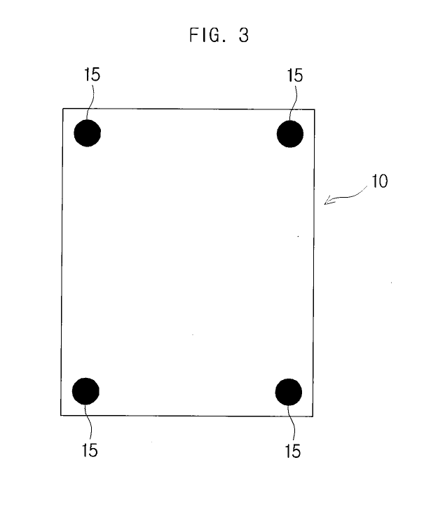

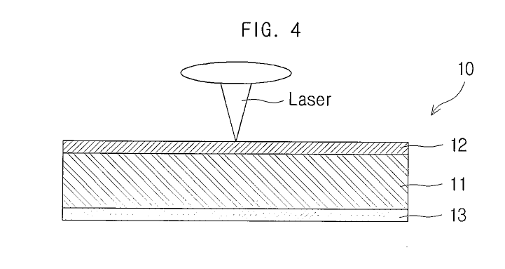

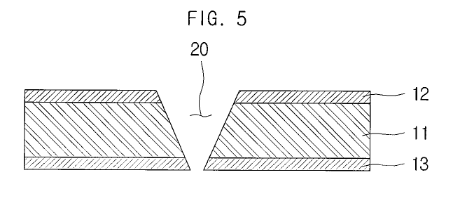

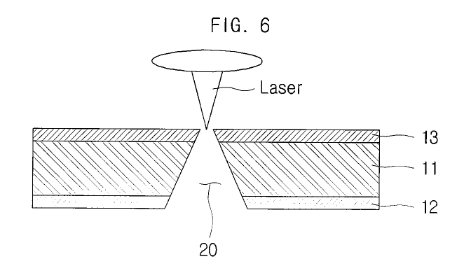

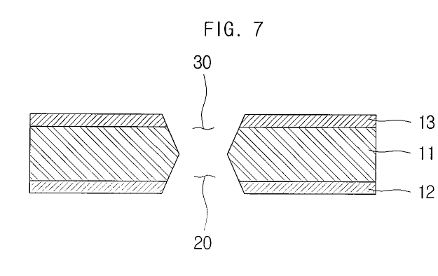

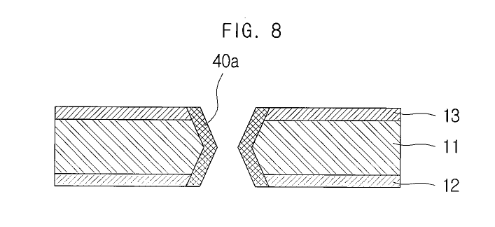

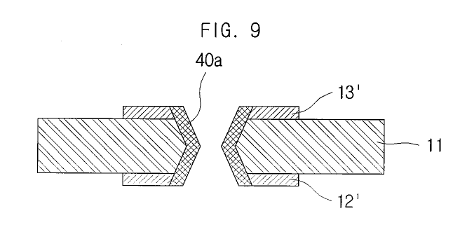

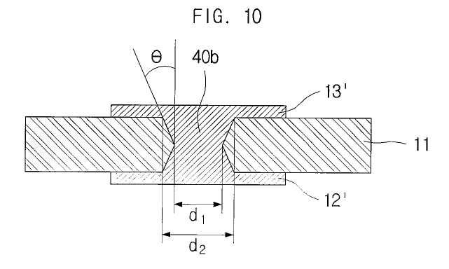

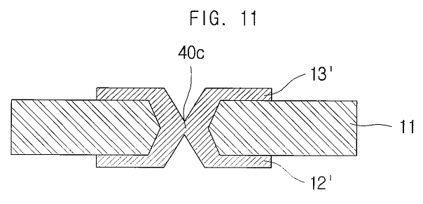

First, a method of manufacturing a printed circuit board according to an aspect of the invention will be described as follows. FIG. 2 is a flowchart illustrating a method of manufacturing a printed circuit board according to an embodiment of the invention, while FIG. 3 through FIG. 11 are drawings that each represents a process in a method of manufacturing a printed circuit board according to an embodiment of the invention. In FIGS. 3 to 11, there are illustrated a substrate 10, an insulator 11, metal films 12 and 13, patterns 12′ and 13′, alignment holes 15, a first hole 20, a second hole 30, and a conductive portion 40a, 40b, and 40c.

First, a substrate 10 can be prepared, and alignment holes 15 can be processed, in preparation for double-sided processing (Operation S110). The alignment holes 15 can be formed to penetrate through the substrate 10 and can be formed in a dummy region at the sides of the substrate 10, as illustrated in FIG. 3. The alignment holes can be used to precisely align the first hole 20 and the second hole 30, each of which will be formed from either side of the substrate 10.

The substrate 10 in which the alignment holes 15 are formed can be a material such as a copper clad laminate that has metal films 12 and 13 formed on either side of an insulator 11. It is also possible to use an insulator that does not have the metal films.

Next, a first hole 20 having a tapered shape can be processed in one side of the substrate 10 using a laser drill (Operation S120, see FIGS. 4 and 5), and then a second hole 30 having a tapered shape and connecting with the first hole 20 can be processed in the other side of the substrate 10 using a laser drill in a position corresponding with that of the first hole 20 (Operation S130, see FIGS. 6 and 7). With the substrate 10 thus processed from both sides, the first hole 20 and the second hole 30 formed from either side of the substrate 10 can be made to overlap each other, as illustrated in FIG. 7, creating an interlayer connection shaped like an hourglass.

A conventional method of processing an interlayer connection using a laser drill may include proceeding with the processing from one direction only. Thus, perforating the metal layer on the opposite side may require a large number of laser shot repetitions, which can prolong processing times and increase costs.

In contrast, this embodiment includes performing the processing from both sides of the substrate 10 separately, as described above. Thus, the processing may be performed with a smaller number of laser shots for each side (for example, twice or fewer), so that the processing times and costs may be reduced. Furthermore, processing the substrate 10 from both sides can make it easier to control the shape of the hole 20 and 30 in either side, as well as the shape of the inside of the hole, whereby the reliability of the product may also be increased.

Afterwards, a conductive portion 40a, 40b, and 40c, which electrically connects either side of the substrate 10 through the first hole 20 and second hole 30, can be formed (Operation S140). A plating process, such as electroless plating and electroplating, can be used as the method of forming the conductive portion 40a, 40b, and 40c.

As illustrated in FIGS. 8 and 9, the conductive portion 40a can be formed over just the inner walls of the first hole 20 and second hole 30, or, as illustrated in FIG. 10, the conductive portion 40b can be formed to completely fill the inside of the hole using, for example, a fill plating method. Moreover, the conductive portion 40c can be formed, as illustrated in FIG. 11, such that the conductive material is filled in only the middle portion.

Afterwards, patterns 12′ and 13′ can be formed on either side of the substrate 10. In cases where a copper clad laminate is used for the substrate 10, as in this particular embodiment, the patterns 12′ and 13′ can be formed by selectively etching the metal films 12 and 13 stacked over either side of the insulator 11.

In cases where an insulator (not shown) that does not have metal films formed on the surfaces is used for the substrate, the method of forming the patterns can include forming seed layers (not shown) on the surfaces of the substrate by using electroless plating, etc., and then performing electroplating to form the patterns. These processes can be performed simultaneously with the process for forming the conductive portion 40a, 40b, and 40c inside the hole 20, 30.

Examples of a printed circuit board manufactured by the method described above are illustrated in FIGS. 9 to 11. The structure of a printed circuit board manufactured using the method described above can have the vias 20 and 30 narrowing from either end towards the middle portion. In other words, the vias can have a shape similar to an hourglass.

In cases where a hole is processed using a laser drill in only one side of the substrate 10, the plating liquid may flow smoothly at the side where the laser was irradiated, but at the side opposite to the side where the laser was irradiated, the hole may be too small or may be blocked altogether during the plating, so that the flow of plating liquid may be impeded. As such, in producing ultra small vias, there is a high risk of deviations occurring in the plating inside the holes, as well as of defects involving unplated portions.

However, in cases where a hole having an hourglass-shape is formed, as in examples of this embodiment, the size of the hole 20 and 30 at either side can be made greater than the size at the inner portion (the middle portion), so that the flow of the plating liquid can remain unimpeded, and the occurrence of plating defects can be reduced. This effect may be maximized if the first hole 20 and the second hole 30 are formed symmetrically. That is, the deviations in plating can be minimized, if the first hole 20 and the second hole 30 are formed in the same position with the same size.

Also, when fill plating (see FIG. 10) or half-fill plating (see FIG. 11), the plating material can be grown from the middle portion of the hole 20 and 30 to completely fill the inside of the hole 20 and 30, allowing the utilization of existing fill plating equipment and plating liquid.

When proceeding with the fill plating, the performance of the plating procedure can be improved by controlling the inclination θ of the hole walls (see FIG. 10). That is, the performance of the fill plating can be especially high when the hole walls are inclined by an angle larger than or equal to 15 degrees and smaller than or equal to 45 degrees.

Besides the inclination of a hole's inner walls, the performance of the plating procedure can also be improved by controlling the ratio of the size of the hole at the surface to the size of the hole in the middle. Looking at the first hole 20, for example, if the lower portion of the first hole is given a size d2 that is between 50% and 70% of the size d1 at the surface of the first hole, the performance of the fill plating can be greatly improved. Here, the lower portion of the first hole 20 refers to the portion where the first hole 20 and second hole 30 connect with each other.

The present embodiment can provide benefits not only in performing fill plating, as described above, but also in filling the hole 20 and 30 with solder resist or resin, as the larger sizes at the openings of the hole on either side compared to the size inside allow the solder resist or resin, etc., to readily fill the hole 20 and 30.

As set forth above, certain embodiments of the invention can be used to reduce the time required for processing vias, and to perform plating procedures for the insides of the vias with greater efficiency. In short, some embodiments of the invention can be used for providing reliable interlayer connections.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

Many embodiments other than those set forth above can be found in the appended claims.

What is claimed is:

1. A method of manufacturing a printed circuit board, the method comprising:
processing a first hole by using a laser drill in one side of a substrate, the first hole having a tapered shape;
processing a second hole by using a laser drill in the other side of the substrate in a position corresponding to a position of the first hole, the second hole having a tapered shape and connecting with the first hole; and
forming a conductive portion by performing plating, the conductive portion electrically connecting both sides of the substrate by way of the first hole and the second hole.

2. The method of claim 1, wherein the conductive portion completely fills the first hole and the second hole.

3. The method of claim 2, wherein an inner wall of the first hole is inclined by an angle of 15 to 45 degrees.

4. The method of claim 2, wherein a bottom portion of the first hole located in a middle of the substrate has a size corresponding to 50% to 70% of a size of a surface portion of the first hole.

5. The method of claim 1, wherein the first hole and the second hole are substantially symmetrical.

6. A printed circuit board comprising:
a substrate;
a first hole formed in one side of the substrate, the first hole having a tapered shape;
a second hole formed in the other side of the substrate and connected with the first hole, the second hole having a tapered shape; and
a conductive portion electrically connecting both sides of the substrate by way of the first hole and the second hole.

7. The printed circuit board of claim 6, wherein the first hole and the second hole are substantially symmetrical.

8. The printed circuit board of claim 6, wherein the conductive portion completely fills the first hole and the second hole.

9. The printed circuit board of claim 8, wherein an inner wall of the first hole is inclined by an angle of 15 to 45 degrees.

10. The printed circuit board of claim 8, wherein a bottom portion of the first hole located in a middle of the substrate has a size corresponding to 50% to 70% of a size of a surface portion of the first hole.
